(19) United States
(12) Patent Application Publication
(10) Pub. No.: US 2020/0035494 A1
(43) Pub. Date: Jan. 30, 2020

(54) Surface Treatment Compositions and Methods

(71) Applicant: Fujifilm Electronic Materials U.S.A., Inc., N.Kingstown, RI (US)

(72) Inventors: William A. Wojtczak, Mesa, AZ (US); Kazutaka Takahashi, Gilbert, AZ (US); Atsushi Mizutani, Shizuoka (JP); Keeyoung Park, Gilbert, AZ (US)

(21) Appl. No.: 16/522,187

(22) Filed: Jul. 25, 2019

Related U.S. Application Data
(60) Provisional application No. 62/712,006, filed on Jul. 30, 2018.
(60) Provisional application No. 62/756,644, filed on Nov. 7, 2018.
(60) Provisional application No. 62/820,905, filed on Mar. 20, 2019.

(51) Int. Cl. H01L 21/30; C09D 5/00; C09D 7/20; H01L 23/29

(52) U.S. Cl. CPC H01L 21/30; H01L 23/293; C09D 7/20; C09D 5/00

(57) ABSTRACT

This disclosure relates to methods and compositions for treating a wafer having a pattern disposed on a surface of the wafer.

### CROSS-REFERENCE TO RELATED APPLICATIONS

The present application claims priority to U.S. Provisional Application Ser. No. 62/820,905, filed on Mar. 20, 2019, U.S. Provisional Application Ser. No. 62/756,644, filed on Nov. 7, 2018, and U.S. Provisional Application Ser. No. 62/712,006, filed on Jul. 30, 2018, the contents of which are hereby incorporated by reference in their entirety.

### TECHNICAL FIELD

This disclosure relates generally to surface treatment, and more particularly to liquid treatment of semiconductor surfaces where formation of a hydrophobic layer is desired.

### BACKGROUND

At sub-20 nm critical dimensions, pattern collapse of FinFET's and dielectric stacks during wet clean and drying has become a major problem in semiconductor manufacturing processes. The conventional theory of pattern collapse implicates high capillary forces during rinse and dry as major contributors leading to the collapse phenomenon. However, other chemical and substrate properties may play an important role as well, namely, liquid surface tension and viscosity, substrate mechanical strength, pattern density and aspect ratio, and cleaner chemistry damage to substrate surfaces.

### SUMMARY

It has been found that low surface tension modifying fluids that impart the surfaces of a semiconductor substrate (e.g., a silicon or copper wafer) with a hydrophobic layer (e.g., a hydrophobic monolayer) can minimize the capillary forces that drive pattern collapse during a drying process. Without wishing to be bound by theory, it is believed that the Laplace pressure is minimized when the contact angle, i.e., the angle a liquid (e.g., water) creates when in contact with a substrate surface, is at or near 90 degrees. This in combination with the presence of a low surface tension fluid can greatly reduce the forces that cause pattern collapse.

In general, this disclosure provides methods and compositions for treating a patterned surface of a semiconductor substrate (e.g., a patterned wafer) where a hydrophobic layer is formed on the surface, thereby minimizing or preventing pattern collapse as the surface is subjected to typical cleaning and drying steps in a semiconductor manufacturing process. The methods disclosed herein employ compositions that form a hydrophobic layer on the surface such that the treated surface has a water contact angle of at least about 50 degrees.

In one aspect, this disclosure features methods for treating a semiconductor substrate having a pattern disposed on a surface of the wafer. Such methods can include contacting the surface with a surface treatment composition to form a surface treatment layer such that the surface treatment layer has a water contact angle of at least about 50 degrees. The surface treatment composition can include (e.g., comprise, consist of, or consist essentially of) at least one solvent (e.g., at least one organic solvent) and at least one trialkylsilyl compound selected from the group consisting of trialklylsilyl alkylsulfonates, trialklylsilyl arylsulfonates, and trialklylsilyl acetates. The surface treatment composition can be substantially free of propylene glycol methyl ether acetate and substantially free of an additional Si-containing compound (e.g., a siloxane such as a disiloxane, a silane, or a silazane) other than the at least one trialkylsilyl compound. The pattern can include a feature having a dimension of at most about 20 nm.

In another aspect, this disclosure features surface treatment compositions that include (e.g., comprise, consist of, or consist essentially of) (1) at least one trialkylsilyl compound in an amount of from about 0.1 wt % to about 15 wt % of the surface treatment composition, the at least one trialkylsilyl compound being selected from the group consisting of trialklylsilyl alkylsulfonates, trialklylsilyl arylsulfonates, and trialklylsilyl acetates; and (2) at least one solvent (e.g., at least one organic solvent) in an amount of from about 1 wt % to about 99 wt % of the surface treatment composition. The surface treatment composition can be substantially free of propylene glycol methyl ether acetate and substantially free of an additional Si-containing compound (e.g., a siloxane such as a disiloxane, a silane, or a silazane) other than the at least one trialkylsilyl compound.

In another aspect, this disclosure features methods for treating a semiconductor substrate having a pattern disposed on a surface of the wafer. Such methods can include contacting the surface with a surface treatment composition to form a surface treatment layer such that the surface treatment layer has a water contact angle of at least about 50 degrees. The surface treatment composition can include (e.g., comprise, consist of, or consist essentially of) at least one siloxane compound and at least one trialkylsilyl compound selected from the group consisting of trialklylsilyl alkylsulfonates, trialklylsilyl arylsulfonates, and trialklylsilyl acetates. The pattern can include a feature having a dimension of at most about 20 nm.

In another aspect, this disclosure features surface treatment compositions that include (e.g., comprise, consist of, or consist essentially of) (1) at least one trialkylsilyl compound in an amount of from about 0.1 wt % to about 15 wt % of the surface treatment composition, the at least one trialkylsilyl compound being selected from the group consisting of trialklylsilyl alkylsulfonates, trialklylsilyl arylsulfonates, and trialklylsilyl acetates; and (2) at least one siloxane compound in an amount of from about 85 wt % to about 99.9 wt % of the surface treatment composition.

In another aspect, this disclosure features methods for treating a semiconductor substrate having a pattern disposed on a surface of the wafer. Such methods can include contacting the surface with a surface treatment composition to form a surface treatment layer such that the surface treatment layer has a water contact angle of at least about 50 degrees. The surface treatment composition can include (e.g., comprise, consist of, or consist essentially of) at least one solvent, at least one sulfonic acid or a salt thereof, and at least one trialkylsilyl compound selected from the group consisting of trialklylsilyl alkylsulfonates, trialklylsilyl arylsulfonates, and trialklylsilyl acetates. The surface treatment composition can be substantially free of an additional Si-containing compound other than the at least one trialkylsilyl compound. The pattern can a feature having a dimension of at most about 20 nm.

In another aspect, this disclosure features surface treatment compositions that include (e.g., comprise, consist of, or consist essentially of) (1) at least one sulfonic acid or a salt thereof in an amount of from about 0.01 wt % to about 10 wt % of the surface treatment composition; (2) at least one trialkylsilyl compound in an amount of from about 0.1 wt % to about 15 wt % of the surface treatment composition, the at least one trialkylsilyl compound being selected from the group consisting of trialklylsilyl alkylsulfonates, trialklylsilyl arylsulfonates, and trialklylsilyl acetates; and (3) at least one solvent in an amount of from about 1 wt % to about 99 wt % of the surface treatment composition. The surface treatment compositions can be substantially free of an additional Si-containing compound other than the at least one trialkylsilyl compound.

In another aspect, this disclosure features articles that include a semiconductor substrate, and a surface treatment composition described herein supported by the semiconductor substrate.

Other features, objects, and advantages of the invention will be apparent from the description and the claims.

### DETAILED DESCRIPTION

In some embodiments, this disclosure relates to surface treatment methods. Such methods can be performed, for example, by contacting the surface (e.g., a surface that has patterns) of a substrate (e.g., a semiconductor substrate such as a silicon or copper wafer) with a surface treatment composition that includes at least one (e.g., two, three, or four) solvent and at least one (e.g., two, three, or four) trialkylsilyl compound selected from the group consisting of trialklylsilyl alkylsulfonates, trialklylsilyl arylsulfonates, and trialklylsilyl acetates. The pattern can include a feature having a dimension of at most about 20 nm. In general, the surface treatment composition forms a surface treatment layer (e.g., a hydrophobic monolayer) on the surface such that the surface has a water contact angle of at least about 50 degrees.

In some embodiments, the surface treatment composition can be substantially free of propylene glycol methyl ether acetate and/or substantially free of an additional Si-containing compound other than the at least one trialkylsilyl compound. As used herein, the term “substantially free” refers to the weight % of a component being at most about 0.1% (e.g., at most about 0.05%, at most about 0.01%, at most about 0.005%, at most about 0.001%, or about 0%).

In some embodiments, semiconductor substrates that can be treated by the surface treatment compositions described herein are constructed of silicon, silicon germanium, silicon nitride, copper, Group III-V compounds such as GaAs, or any combination thereof. In some embodiments, the semiconductor substrate can be a silicon wafer, a copper wafer, a silicon dioxide wafer, a silicon nitride wafer, a silicon oxynitride wafer, a carbon doped silicon oxide wafer, a SiGe wafer, or a GaAs wafer. The semiconductor substrates may additionally contain exposed integrated circuit structures such as interconnect features (e.g., metal lines and dielectric materials) on their surfaces. Metals and metal alloys used for interconnect features include, but are not limited to, aluminum, aluminum alloyed with copper, copper, titanium, tantalum, cobalt, nickel, silicon, polysilicon, titanium nitride, tantalum nitride, tin, tungsten, SnAg, SnAg/Ni, CuNiSn, CuCoCu, and/or CoSn. The semiconductor substrate may also contain layers of interlayer dielectrics, silicon oxide, silicon nitride, titanium nitride, silicon carbide, silicon oxide carbide, silicon oxide nitride, titanium oxide, and/or carbon doped silicon oxides.

In some embodiments, the semiconductor substrate surface to be treated by the surface treatment compositions described herein includes features containing SiO₂, SiN, TiN, SiOC, SiON, Si, SiGe, Ge, and/or W. In some embodiments, the substrate semiconductor surface includes features containing SiO₂ and/or SiN.

In general, the semiconductor substrate surface to be treated by the surface treatment compositions described herein includes patterns formed by a prior semiconductor manufacturing process (e.g., a lithographic process including applying a photoresist layer, exposing the photoresist layer to an actinic radiation, developing the photoresist layer, etching the semiconductor substrate beneath the photoresist layer, and/or removing the photoresist layer). In some embodiments, the patterns can include features having at least one (e.g., two or three) dimension (e.g., a length, a width, and/or a depth) of at most about 20 nm (e.g., at most about 15 nm, at most about 10 nm, or at most about 5 nm) and/or at least about 1 nm (e.g., at least about 2 nm or at least about 5 nm).

In general, the surface treatment compositions described herein can include at least one (two, three, or four) trialkylsilyl compound and at least one (e.g., two, three, or four) solvent. In some embodiments, the trialkylsilyl compound can include a SiR₃ group, in which each R, independently, can be C₁-C₁₆ alkyl or C₁-C₁₆ haloalkyl. For example, the trialkylsilyl compound can include a trimethylsilyl group, a triethylsilyl group, a tripropylsilyl group, or a tributylsilyl group.

In some embodiments, the trialkylsilyl compound can be selected from the group consisting of trialklylsilyl alkylsulfonates, trialklylsilyl arylsulfonates, and trialklylsilyl acetates. Examples of suitable trialkylsilyl compounds that can be used in the surface treatment compositions described herein include trialkylsilyl methanesulfonate, trialkylsilyl trifluoromethanesulfonate (i.e., trialkylsilyl triflate), trialkylsilyl perfluorobutanesulfonate, trialkylsilyl p-toluenesulfonate, trialkylsilyl benzenesulfonate, and trialkylsilyl trifluoroacetate, trialkylsilyl trichloroacetate, and trialkylsilyl tribromoacetate. A specific example of suitable trialkyl silyl compounds is trimethylsilyl trifluoromethanesulfonate.

In some embodiments, the at least one trialkylsilyl compound can be from at least about 0.1 wt % (e.g., at least about 0.2 wt %, at least about 0.3 wt %, at least about 0.4 wt %, at least about 0.5 wt %, at least about 0.6 wt %, at least about 0.7 wt %, at least about 0.8 wt %, at least about 0.9 wt %, at least about 1 wt %, at least about 2 wt %, at least about 3 wt %, at least about 4 wt %, at least about 5 wt %, at least about 6 wt %, at least about 7 wt %, at least about 8 wt %, or at least about 9 wt %) to at most about 15 wt % (e.g., at most about 14 wt %, at most about 13 wt %, at most about 12 wt %, at most about 11 wt %, at most about 10 wt %, at most about 9 wt %, at most about 8 wt %, at most about 7 wt %, at most about 6 wt %, at most about 5 wt %, at most about 4 wt %, at most about 3 wt %, at most about 2 wt %, at most about 1 wt %, at most about 0.9 wt %, at most about 0.8 wt %, at most about 0.7 wt %, at most about 0.6 wt %, or at most about 0.5 wt %) of the surface treatment compositions described herein.

In some embodiments, the surface treatment compositions described herein can include at least one solvent (e.g., at least one organic solvent), such as anhydrides, nitriles, glycol ethers, glycol ether acetates, alkanes, aromatic hydrocarbons, sulfones, sulfoxides, ketones, aldehydes, esters, lactams, lactones, acetals, hemiacetals, alcohols, carboxylic acids (e.g., those having a pKa of at least 0), sulfonic acids, and ethers. Examples of suitable solvents include acetic anhydride, propionic anhydride, trifluoroacetic anhydride, acetonitrile, a C₆-C₁₆ alkane, toluene, xylene, mesitylene, tetraethylene glycol dimethyl ether, propylene glycol dimethyl ether, ethylene glycol dimethyl ether, dipropylene glycol dimethyl ether, diethylene glycol dimethyl ether, diethylene glycol diethyl ether, dipropylene glycol dibutylether, n-dibutyl ether, anisole, dimethyl sulfone, dimethyl sulfoxide (DMSO), sulfolane, propylene carbonate, methyl ethyl ketone (MEK), cyclohexanone, n-butyl acetate, hexyl acetate, benzyl acetate, amyl acetate, ethyl propionate, ethyl butanoate, propyl propionate, methyl butanoate, acetic acid, formic acid, methanesulfonic acid, trifluoroacetic acid, isobutyl methyl ketone, N-methyl-pyrrolidone (NMP), hydrofluoroethers (e.g., methyl nonafluorobutyl ether and methyl nonafluoroisobutyl ether), or a combination thereof. In some embodiments, the surface treatment compositions described herein can include water or can be substantially free of water.

In some embodiments, the at least one solvent can be from at least about 1 wt % (e.g., at least about 5 wt %, at least about 10 wt %, at least about 20 wt %, at least about 30 wt %, at least about 40 wt %, at least about 50 wt %, at least about 60 wt %, at least about 70 wt %, at least about 75 wt %, at least about 80 wt %, at least about 85 wt %, at least about 90 wt %, or at least about 95 wt %) to at most about 99.9 wt % (e.g., at most about 99 wt %, at most about 95 wt %, at most about 90 wt %, at most about 85 wt %, at most about 75 wt %, at most about 65 wt %, at most about 55 wt %, at most about 45 wt %, at most about 35 wt %, or at most about 25 wt %) of the surface treatment compositions described herein.

In some embodiments, the surface treatment compositions described herein can further include at least one (e.g., two, three, or four) sulfonic acid or a salt thereof. The at least one sulfonic acid can include a sulfonic acid of formula (I): R—SO₃H, in which R is a C₁-C₁₆ alkyl group (e.g., methyl or octyl) optionally substituted by one or more (e.g., two, three, or four) halo (e.g., F, Cl, Br, or I), or a phenyl group optionally substituted by one or more (e.g., two, three, or four) C₁-C₁₆ alkyl (e.g., a C₁₂ alkyl group). Examples of suitable sulfonic acid include p-xylene-2-sulfonic acid, p-toluenesulfonic acid, 4-dodecylbenzenesulfonic acid, and 1H,1H,2H,2H-perfluorooctanesulfonic acid. Suitable salts of sulfonic acids include sodium salts, potassium salts, and ammonium salts.

In some embodiments, the at least one sulfonic acid or a salt thereof can be from at least about 0.01 wt % (e.g., at least about 0.02 wt %, at least about 0.04 wt %, at least about 0.05 wt %, at least about 0.06 wt %, at least about 0.08 wt %, at least about 0.1 wt %, at least about 0.2 wt %, at least about 0.3 wt %, at least about 0.4 wt %, or at least about 0.5 wt %) to at most about 10 wt % (e.g., at most about 8 wt %, at most about 6 wt %, at most about 5 wt %, at most about 4 wt %, at most about 2 wt %, at most about 1 wt %, at most about 0.9 wt %, at most about 0.8 wt %, at most about 0.7 wt %, at most about 0.6 wt %, at most about 0.5 wt %, at most about 0.4 wt %, at most about 0.3 wt %, at most about 0.2 wt %, at most about 0.1 wt %, or at most about 0.05 wt %) of the surface treatment compositions described herein.

It has been surprisingly found that the sulfonic acid or a salt thereof described above can significantly reduce the number of collapsed pattern features (e.g., having a dimension of at most about 20 nm) on a semiconductor substrate surface during a drying step typically used in the semiconductor manufacturing process after the surface is treated by the surface treatment compositions described herein.

In some embodiments, when the surface treatment compositions described herein include a Si-containing compound in addition to the at least one trialkylsilyl compound, the at least one solvent can include at least one (e.g., two, three, or four) siloxane compound. A siloxane compound can be a disiloxane, an oligosiloxane, a cyclosilxoane, or a polysiloxane. As used herein, the term “oligosiloxane” refers to a compound having 3-6 siloxane units, and the term “polysiloxane” refers to a compound having more than 6 siloxane units.

Examples of suitable siloxane compounds that can be used in the surface treatment compositions described herein include hexamethyldisiloxane, 1,3-diphenyl-1,3-dimethyldisiloxane, 1,1,3,3-tetramethyldisiloxane, 1,1,1-triethyl-3,3-dimethyldisiloxane, 1,1,3,3-tetra-n-octyldimethyldisiloxane, bis(nonafluorohexyl)tetramethyldisiloxane, 1,3-bis(trifluoropropyl)tetramethyldisiloxane, 1,3-di-n-butyltetramethyldisiloxane, 1,3-di-n-octyltetramethyldisiloxane, 1,3-diethyltetramethyldisiloxane, 1,3-diphenyltetramethyldisiloxane, hexa-n-butyldisiloxane, hexaethyldisiloxane, hexavinyldisiloxane, 1,1,1,3,3-pentamethyl-3-acetoxydisiloxane, 1-allyl-1,1,3,3-tetramethyldisiloxane, 1,3-bis(3-aminopropyl)tetramethyldisiloxane, 1,3-bis(heptadecafluoro-1,1,2,2-tetrahydrodecyl)-tetramethyldisiloxane, 1,3-divinyltetraphenyldisiloxane, 1,3-divinyltetramethyldisiloxane, 1,3-diallyltetrakis(trimethylsiloxy)disiloxane, 1,3-diallyltetramethyldisiloxane, 1,3-diphenyltetrakis(dimethylsiloxy)disiloxane, (3-chloropropyl)pentamethyldisiloxane, 1,3-divinyltetrakis(trimethylsiloxy)disiloxane, 1,1,3,3-tetraisopropyldisiloxane, 1,1,3,3-tetravinyldimethyldisiloxane, 1,1,3,3-tetracyclopentyldichlorodisiloxane, vinylpentamethyldisiloxane, 1,3-bis(3-chloroisobutyl)tetramethyldisiloxane, hexaphenyldisiloxane, 1,3-bis[(bicyclo[2.2.1]hept-2-enyl)ethyl]tetramethyldisiloxane, 1,1,1-triethyl-3,3,3-trimethyldisiloxane, 1,3-bis(3-methacryloxypropyl)tetramethyldisiloxane, 1,3-bis(chloromethyl)tetramethyldisiloxane, 1,1,3,3-tetramethyl-1,3-diethoxydisiloxane, 1,1,3,3-tetraphenyldimethyldisiloxane, methacryloxypentamethyldisiloxane, pentamethyldisiloxane, 1,3-bis(3-chloropropyl)tetramethyldisiloxane, 1,3-bis(4-hydroxybutyl)tetramethyldisiloxane, 1,3-bis(triethoxysilylethyl)tetramethyldisiloxane, 3-aminopropylpentamethyldisiloxane, 1,3-bis(2-aminoethylaminomethyl)-tetramethyldisiloxane, 1,3-bis(3-carboxypropyl)tetramethyldisiloxane, 1,3-dichloro-1,3-diphenyl-1,3-dimethyldisiloxane, 1,3-diethynyltetramethyldisiloxane, n-butyl-1,1,3,3-tetramethyldisiloxane, 1,3-dichlorotetraphenyldisiloxane, 1,3-dichlorotetramethyldisiloxane, 1,3-di-t-butyldisiloxane, 1,3-dimethyltetramethoxydisiloxane, 1,3-divinyltetraethoxydisiloxane, 1,1,3,3-tetraethoxy-1,3-dimethyldisiloxane, vinyl-1,1,3,3-tetramethyldisiloxane, platinum-[1,3-bis(cyclohexyl)imidazol-2-ylidene hexachlorodisiloxane, 1,1,3,3-tetraisopropyl-1-chlorodisiloxane, 1,1,1-trimethyl-3,3,3-triphenyldisiloxane, 1,3-bis(trimethylsiloxy)-1,3-dimethyldisiloxane, 3,3-diphenyltetramethyltrisiloxane, 3-phenylheptamethyltrisiloxane, hexamethylcyclotrisiloxane, n-propylheptamethyltrisiloxane, 1,5-diethoxyhexamethyltrisiloxane, 3-ethylheptamethyltrisiloxane, 3-(tetrahydrofurfuryloxypropyl)heptamethyltrisiloxane, 3-(3,3,3-trifluoropropyl)heptamethyltrisiloxane, 1,1,3,5,5-pentaphenyl-1,3,5-trimethyltrisiloxane, octamethyltrisiloxane, 1,1,5,5-tetraphenyl-1,3,3,5-tetramethyltrisiloxane, hexaphenylcyclotrisiloxane, 1,1,1,5,5,5-hexamethyltrisiloxane, octachlorotrisiloxane, 3-phenyl-1,1,3,5,5-pentamethyltrisiloxane, (3,3,3-trifluoropropyl)methylcyclotrisiloxane, 1,3,5-trivinyl-1,1,3,5,5-pentamethyltrisiloxane, 1,3,5-trivinyl-1,3,5-trimethylcyclotrisiloxane, 3-(3-acetoxypropyl)heptamethyltrisiloxane, 3-(m-pentadecylphenoxypropyl)heptamethyltrisiloxane, limonenyltrisiloxane, 3-dodecylheptamethyltrisiloxane, 3-octylheptamethyltrisiloxane, 1,3,5-triphenyltrimethylcyclotrisiloxane, 1,1,1,3,3,5,5-heptamethyltrisiloxane, 1,1,3,3,5,5-hexamethyltrisiloxane, 1,1,1,5,5,5-hexaethyl-3-methyltrisiloxane, 1,5-dichlorohexamethyltrisiloxane, 3-triacontylheptamethyltrisiloxane, 3-(3-hydroxypropyl)heptamethyltrisiloxane, hexamethylcyclomethylphosphonoxytrisiloxane, 3-octadecylheptamethyltrisiloxane, furfuryloxytrisiloxane, tetrakis(dimethylsiloxy)silane, 1,1,3,3,5,5,7,7-octamethyltetrasiloxane, a diphenyl siloxane-dimethylsiloxane copolymer, 1,3-diphenyl-1,3-dimethyldisiloxane, octamethylcyclotetrasiloxane, 1,3-bis(trimethylsiloxy)-1,3-dimethyldisiloxane, a dimethylsiloxane-[65-70% (60% propylene oxide/40% ethylene oxide)] block copolymer, bis(hydroxypropyl)tetramethyldisiloxane, tetra-n-propyltetramethylcyclotetrasiloxane, octaethylcyclotetrasiloxane, decamethyltetrasiloxane, dodecamethylcyclohexasiloxane, dodecamethylpentasiloxane, tetradecamethylhexasiloxane, hexaphenylcyclotrisiloxane, polydimethylsiloxane, polyoctadecylmethylsiloxane, hexacosyl terminated polydimethylsiloxane, decamethylcyclopentasiloxane, poly(3,3,3-trifluoropropylmethylsiloxane), trimethylsiloxy terminated polydimethylsiloxane, 1,1,3,3,5,5,7,7,9,9-decamethylpentasiloxane, and triethylsiloxy terminated polydiethylsiloxane.

In some embodiments, the at least one siloxane compound can be from at least about 0.1 wt % (e.g., at least about 1 wt %, at least about 5 wt %, at least about 10 wt %, at least about 20 wt %, at least about 30 wt %, at least about 40 wt %, at least about 50 wt %, at least about 60 wt %, at least about 70 wt %, at least about 80 wt %, at least about 90 wt %, at least about 91 wt %, at least about 93 wt %, at least about 95 wt %, at least about 97 wt %, or at least about 99 wt %) to at most about 99.9 wt % (e.g., at most about 99 wt %, at most about 98 wt %, at most about 96 wt %, at most about 94 wt %, at most about 92 wt %, at most about 90 wt %, at most about 85 wt %, at most about 80 wt %, at most about 75 wt %, at most about 70 wt %, at most about 65 wt %, at most about 60 wt %, at most about 55 wt %, or at most about 50 wt %) of the surface treatment compositions described herein.

In some embodiments, the surface treatment compositions described herein can include only two types of components, i.e., (1) at least one trialkylsilyl compound and (2) at least one solvent (e.g., a siloxane compound). In some embodiments, the surface treatment compositions described herein can include only three types of components, i.e., (1) at least one trialkylsilyl compound, (2) at least one sulfonic acid, and (3) at least one solvent.

Without wishing to be bound by theory, it is believed that the surface treatment compositions described herein can form a surface treatment layer (e.g., a hydrophobic layer such as a hydrophobic monolayer) on a patterned surface of a semiconductor substrate such that the patterned surface has a water contact angle of at least about 50 degrees (e.g., at least about 55 degrees, at least about 60 degrees, at least about 65 degrees, at least about 70 degrees, at least about 75 degrees, at least about 80 degrees, at least about 85 degrees, at least about 89 degrees, at least about 90 degrees, at least about 95 degrees, or at least about 100 degrees) and/or at most about 175 degrees. Without wishing to be bound by theory, it is believed that such a surface treatment layer can prevent or minimize the collapse of the patterned features (e.g., having a dimension of at most about 20 nm) on a semiconductor substrate surface during a drying step typically used in the semiconductor manufacturing process after the surface is treated by the surface treatment compositions described herein.

In some embodiments, the surface treatment compositions described herein can specifically exclude or substantially free of one or more of the additive components, in any combination, if more than one. Such components are selected from the group consisting of non-aromatic hydrocarbons, protic solvents (e.g., alcohols or amides), lactones (e.g., those with 5- or 6-membered rings), propylene glycol methyl ether acetate, Si-containing compounds (e.g., siloxanes such as disiloxanes; silanes; silazanes such as disilazanes, cyclic silazanes or heterocyclic silazanes; and those having a Si—H group or an aminosilyl group), polymers, oxygen scavengers, quaternary ammonium salts including quaternary ammonium hydroxides, amines, bases (such as alkaline bases (e.g., NaOH, KOH, LiOH, Mg(OH)₂, and Ca(OH)₂)), surfactants, defoamers, fluoride-containing compounds (e.g., HF, H₂SiF₆, H₂PF₆, HBF₄, NH₄F, and tetraalkylammonium fluoride), oxidizing agents (e.g., peroxides, hydrogen peroxide, ferric nitrate, potassium iodate, potassium permanganate, nitric acid, ammonium chlorite, ammonium chlorate, ammonium iodate, ammonium perborate, ammonium perchlorate, ammonium periodate, ammonium persulfate, tetramethylammonium chlorite, tetramethylammonium chlorate, tetramethylammonium iodate, tetramethylammonium perborate, tetramethylammonium perchlorate, tetramethylammonium periodate, tetramethylammonium persulfate, urea hydrogen peroxide, and peracetic acid), abrasives, silicates, hydroxycarboxylic acids, carboxylic and polycarboxylic acids lacking amino groups, silanes (e.g., alkoxysilanes), cyclic compounds (e.g., cyclic compounds containing at least two rings, such as substituted or unsubstituted naphthalenes, or substituted or unsubstituted biphenylethers) other than the cyclosiloxanes described herein, chelating agents (e.g., azoles, diazoles, triazoles, or tetrazoles), corrosion inhibitors (such as azole or non-azole corrosion inhibitors), buffering agents, guanidine, guanidine salts, pyrrolidone, polyvinyl pyrrolidone, metal halides, and metal-containing catalysts.

In some embodiments, the surface treatment methods described herein can further include contacting the surface of a substrate with at least one aqueous cleaning solution before contacting the surface with a surface treatment composition. In such embodiments, the at least one aqueous cleaning solution can include water, an alcohol, aqueous ammonium hydroxide, aqueous hydrochloric acid, aqueous hydrogen peroxide, an organic solvent, or a combination thereof.

In some embodiments, the surface treatment methods described herein can further include contacting the surface of a substrate with a first rinsing solution (e.g., water, an organic solvent such as isopropanol, or a combination thereof) after contacting the surface with the at least one aqueous cleaning solution but before contacting the surface with the surface treatment composition. In some embodiments, the surface treatment methods described herein can further include contacting the surface with a second rinsing solution (e.g., water, an organic solvent such as isopropanol, or a combination thereof) after contacting the surface with the surface treatment composition. In some embodiments, the surface treatment methods described herein can further include drying the surface (e.g., after any of the steps of contacting the surface with first rinsing solution, the surface treatment composition, or the second rinsing solution). In some embodiments, the surface treatment methods described herein can further include removing the surface treatment layer from the surface.

In some embodiments, this disclosure provides methods for cleaning a semiconductor substrate (e.g., a wafer) having a pattern disposed on a surface of the substrate. Such methods can be performed, for example, by:

a) optionally, contacting the surface with an aqueous cleaning solution;

b) optionally, contacting the surface with a first rinsing solution;

c) contacting the surface with a surface treatment composition, wherein the surface treatment composition includes at least one trialkylsilyl compound and at least one solvent, and the surface treatment composition forms a surface treatment layer on the surface such that the surface has a water contact angle of at least about 50 degrees;

d) optionally, contacting the surface with a second rinsing solution;

e) drying the surface; and

f) optionally, removing the surface treatment layer to form a cleaned, patterned surface.

In such embodiments, the pattern can include a feature having a dimension of at most about 20 nm.

In step a) of the above described methods, the substrate (e.g., a wafer) bearing a patterned surface can optionally be treated with one or more aqueous cleaning solutions. When the patterned surface is treated with two or more aqueous cleaning solutions, the cleaning solutions can be applied sequentially. The aqueous cleaning solutions can be water alone, an organic solvent alone, or can be solutions containing water, a solute, and optionally an organic solvent. In some embodiments, the aqueous cleaning solutions can include water, an alcohol (e.g., a water soluble alcohol such as isopropanol), an aqueous ammonium hydroxide solution, an aqueous hydrochloric acid solution, an aqueous hydrogen peroxide solution, an organic solvent (e.g., a water soluble organic solvent), or a combination thereof.

In step b), the cleaning solution from step a) can be optionally rinsed away using a first rinsing solution. The first rinsing solution can include water, an organic solvent (e.g., isopropanol), or an aqueous solution containing an organic solvent. In some embodiments, the first rinsing solution is at least partially miscible with the cleaning solution used in step a). In some embodiments, step b) can be omitted when the cleaning solution used in step a) is not moisture sensitive or does not contain any appreciable amount of water.

In step c), the substrate surface can be treated with a surface treatment composition of the disclosure described above to form a modified surface having a surface treatment layer (e.g., a hydrophobic layer). The modified surface thus formed can be hydrophobic and can have a water contact angle of at least about 50 degrees. In some embodiments, the contact angle can be at least about 55 degrees (e.g., at least about 60 degrees, at least about 65 degrees, at least about 70 degrees, at least about 75 degrees, at least about 80 degrees, at least about 85 degrees, at least about 90 degrees, at least about 95 degrees, or at least about 100 degrees) and/or at most about 175 degrees. In some embodiments, this step can be performed at a temperature of about 20-35° C. for a process time ranging from about 10 seconds to about 300 seconds.

In step d), after the substrate surface is treated with a surface treatment composition, the surface can be rinsed with a second rinsing solution. The second rinsing solution can include water, an organic solvent (e.g., isopropanol), or an aqueous solution containing an organic solvent. In some embodiments, this step can be performed at a temperature of about 20-70° C.

In step e), the substrate surface can be dried (e.g., by using a pressurized gas). Without wishing to be bound by theory, it is believed that, after the substrate surface is treated with a surface treatment composition described herein, the collapse of patterns on the surface during this drying step is minimized.

In step f), after the drying step, the surface treatment layer (e.g., a hydrophobic layer) can optionally be removed. In general, the surface treatment layer can be removed by a number of methods depending on the chemical characteristics of the modified surface. Suitable methods for removing the surface treatment layer include plasma sputtering; plasma ashing; thermal treatment at atmospheric or sub atmospheric pressure; treatment with an acid, base, oxidizing agent or solvent containing condensed fluid (e.g., supercritical fluids such as supercritical CO₂); vapor or liquid treatment; UV irradiation; or combinations thereof.

The semiconductor substrate having a cleaned, patterned surface prepared by the method described above can be further processed to form one or more circuits on the substrate or can be processed to form into a semiconductor device (e.g., an integrated circuit device such as a semiconductor chip) by, for example, assembling (e.g., dicing and bonding) and packaging (e.g., chip sealing).

In some embodiments, this disclosure features articles (e.g., an intermediate semiconductor article formed during the manufacturing of a semiconductor device) that includes a semiconductor substrate, and a surface treatment composition described herein supported by the semiconductor substrate. The surface treatment composition can include at least one trialkylsilyl compound and at least one solvent, as described above.

In some embodiments, this disclosure features kits that include a first container including at least one trialkylsilyl compound described above; and a second container including at least one solvent described above. If desired, the first or second container can further include at least one organic solvent to form a solution with the component in each container. In some embodiments, the components in the first and second containers can be mixed to form a surface treatment composition at the point of use right before applying the surface treatment composition to a surface of a semiconductor substrate. Without wishing to be bound by theory, it is believed that such a method is particularly suitable for a surface treatment composition having a relatively short shelf life. In embodiments where a surface treatment composition has a relatively long shelf life, the components in the first and second containers can be mixed to form one solution, which can be stored for a relative long period of time before use.

The present disclosure is illustrated in more detail with reference to the following examples, which are for illustrative purposes and should not be construed as limiting the scope of the present disclosure.

### Example 1

Surface Treatment Solutions (i.e., formulations 1-16) were prepared by mixing the components at room temperature. The compositions of formulations 1-16 are summarized in Table 1 below. All percentages listed in Table 1 are weight percentages, unless indicated otherwise.

Semiconductor substrates containing SiO₂ films were treated with formulations 1-16 and the contact angles of the treated surfaces were measured as follows. The coupons containing SiO₂ films on Si substrates were cut into 1×1 inch squares and then rinsed with isopropanol at room temperature for 30 seconds. The coupons were immersed vertically into 100 mL of stirred (50 RPM) Surface Treatment Solutions and were kept at room temperature for 30 seconds. The coupons were then rinsed with isopropanol at 50° C. for 60 seconds and dried by using pressurized nitrogen gas.

The coupons were placed on the AST VCA 3000 Contact Angle Tool and the following procedure was followed to measure the contact angles:

1. Place the SiO₂ coupon onto the stage.

2. Raise the stage upward by rotating Vertical Knob clockwise until the specimen is just below the needle.

3. Dispense a drop of De-ionized water, lightly touching the specimen surface, then lower the specimen until the droplet separates from the needle tip.

4. Center the drop across the field-of-view using transverse knob for stage adjustment.

5. Focus the drop in field-of-view to get a sharp image by moving the stage along guide rails.

6. Click the “AutoFAST” button to freeze the image and calculate. Two numbers will be displayed; these are the left and right contact angles.

7. To calculate manually, use the mouse to place five markers around the droplet.

8. Select the droplet icon from the Main Menu to calculate the contact angle.

9. This will create a curve fit and tangent lines on the image. Two numbers will be displayed in the left-hand-corner of the screen; these are the left and right contact angles.

10. Repeat above procedure at 3 substrate sites and average the resulting contact angles and report the average result in Table 1.

TABLE 1

| Form. | | | Liquid | |
|---|---|---|---|---|
| # | Si-Containing Compound | Solvent(s) | Appearance | SiO₂ CA¹ |
| 1 | 4% trimethylsilyl triflate | 95% acetic acid | Clear | 96.2 |
| | | 1% acetic anhydride | | |
| 2 | 4% trimethylsilyl triflate | 96% propylene carbonate | Orange | 101.5 |
| 3 | 4% trimethylsilyl triflate | 96% PGMEA² | Clear | 91.8 |
| 4 | 4% trimethylsilyl triflate | 96% MEK | Clear | 92.8 |
| 5 | 4% trimethylsilyl triflate | 96% DMSO | Clear | 89.9 |
| 6 | 4% trimethylsilyl triflate | 96% n-Decane | White | 100.5 |
| 7 | 4% trimethylsilyl triflate | 96% NMP | Clear | 94.0 |
| 8 | 4% trimethylsilyl triflate | 96% Tetraglyme³ | Red | 92.7 |
| 9 | 4% trimethylsilyl triflate | 96% EGBE⁴ | Clear | 32.2 |
| 10 | 4% trimethylsilyl triflate | 96% DGDE⁵ | Red | 81.5 |
| 11 | 4% trimethylsilyl triflate | 96% HMDSO⁶ | Clear | 100.2 |
| 12 | 4% trimethylsilyl triflate | 96% t-amyl alcohol | Clear | 34.2 |
| 13 | 4% trimethylsilyl triflate | 96% acetic acid | Clear | 94.8 |
| 14 | 10% trimethylsilyl triflate | 90% acetic acid | Clear | 101.3 |
| 15 | 4% trimethylsilyl triflate | 96% anisole | Clear | 96.3 |
| 16 | 4% trimethylsilyl triflate | 96% hexyl acetate | Clear | 95.2 |
| 17 | 4% trimethylsilyl triflate | 96% n-butyl acetate | Light yellow | 100.3 |
| 18 | 4% trimethylsilyl triflate | 96% HFE- 7100⁷ | Clear | 95.3 |

¹“CA” refers to contact angle (degrees)
²“PGMEA” refers to propylene glycol methyl ether acetate
³“Tetraglyme” refers to tetraethylene glycol dimethyl ether
⁴“EGBE” refers to ethylene glycol butyl ether
⁵“DGDE” refers to diethylene glycol diethyl ether
⁶“HMDSO” refers to hexamethyldisiloxane
⁷“HFE-7100” refers to methyl nonafluorobutyl ether and methyl nonafluroisobutyl ether mixture

As shown in Table 1, formulations 1-8, 10, 11, and 13-18 (which contained a trimethylsilyl compound and at least one suitable solvent) exhibited relatively large contact angles on a SiO₂ surface.

### Example 2

Surface Treatment Solutions (i.e., formulations 19-44) were prepared by mixing the components at room temperature. The compositions of formulations 19-44 are summarized in Tables 2-5 below. All percentages listed in Tables 2-5 are weight percentages, unless indicated otherwise.

Semiconductor substrates containing SiO₂ films were treated with formulations 19-44. The contact angles of the treated surfaces were measured as described in Example 1. The number of uncollapsed features were determined from SEM photographs of the substrates after treatment.

TABLE 2

| Form. | Si-Containing | | Sulfonic | SiO₂ | Uncollapsed | |
|---|---|---|---|---|---|---|
| # | Compound | Solvent(s) | acid | CA¹ | features | Stiffness |
| 19 | 5% trimethylsilyl triflate | 95% acetic acid | None | 87.6 | 92.82% | 38 mN/m |
| 20 | 5% trimethylsilyl triflate | 94.9% acetic acid | 0.1% pTSA² | 88.7 | 99.22% | 38 mN/m |
| 21 | 5% trimethylsilyl triflate | 94.9% acetic acid | 0.1% DBSA³ | 88.5 | 97.33% | 38 mN/m |
| 22 | 5% trimethylsilyl triflate | 94.9% acetic acid | 0.1% PFOSA⁴ | 87.7 | 96.20% | 38 mN/m |

¹“CA” refers to contact angle (degrees)
²“pTSA” refers to p-toluenesulfonic acid
³“DBSA” refers to 4-dodecylbenzenesulfonic acid
⁴“PFOSA” refers to 1H,1H,2H,2H-perfluorooctanesulfonic acid

As shown in Table 2, formulations 19-22 (each of which contained a sulfonic acid) surprisingly exhibited significantly higher percentages of uncollapsed features than formulation 17 (which contained no sulfonic acid).

TABLE 3

| | | | Uncol- | | |
|---|---|---|---|---|---|
| Form. | | | lapsed | | |
| # | Si-Containing Compound | Solvent(s) | features | Stiffness | |
| 23 | 5% trimethylsilyl triflate | 95% butyl acetate | 93.2% | 32.5 | mN/m |
| 24 | 5% trimethylsilyl triflate | 95% benzyl acetate | 90.7% | 32.5 | mN/m |
| 25 | 5% trimethylsilyl triflate | 95% hexyl acetate | 92.9% | 32.5 | mN/m |
| 26 | 5% trimethylsilyl triflate | 95% amyl acetate | 92.6% | 32.5 | mN/m |
| 27 | 5% trimethylsilyl triflate | 95% butyl acetate | 81.4% | 27 | mN/m |
| 28 | 5% trimethylsilyl triflate | 95% acetic anhydride | 75.0% | 27 | mN/m |
| 29 | 5% trimethylsilyl triflate | 95% propionic anhydride | 70.9% | 27 | mN/m |
| 30 | 5% trimethylsilyl triflate | 95% trifluoroacetic | 81.6% | 27 | mN/m |
| | | anhydride | | | |
| 31 | 5% trimethylsilyl triflate | 95% butyl acetate | 76.3% | 26 | mN/m |
| 32 | 5% trimethylsilyl triflate | 95% acetonitrile | 77.9% | 26 | mN/m |
| 33 | 5% trimethylsilyl triflate | 95% butyl acetate | 74.9% | 24 | mN/m |
| 34 | 5% trimethylsilyl triflate | 95% ethyl propionate | 76.7% | 24 | mN/m |
| 35 | 5% trimethylsilyl triflate | 95% ethyl butanoate | 73.0% | 24 | mN/m |
| 36 | 5% trimethylsilyl triflate | 95% propyl propionate | 77.3% | 24 | mN/m |
| 37 | 5% trimethylsilyl triflate | 95% methyl butanoate | 74.3% | 24 | mN/m |

Stiffness is a property of the Si pillar on the pattern wafer to bending and is reported as a force in units of mN/m. Table 3 shows the performance of formulations 23-37 as a function of Si Pillar stiffness. As shown in Table 3, Si pillars with low stiffness were more prone to collapse when subjected to drying stresses than those with higher stiffness.

TABLE 4

| | | | Uncol- | |
|---|---|---|---|---|
| Form. | Si-Containing | | lapsed | |
| # | Compound | Solvent(s) | features | Stiffness |
| 38 | 3% trimethylsilyl | 97% acetic | 87.7% | 34 mN/m |
| | triflate | acid | | |
| 39 | 5% trimethylsilyl | 95% acetic | 89.2% | 34 mN/m |
| | triflate | acid | | |
| 40 | 10% trimethylsilyl | 90% acetic | 91.7% | 34 mN/m |
| | triflate | acid | | |
| 41 | 15% trimethylsilyl | 85% acetic | 93.3% | 34 mN/m |
| | triflate | acid | | |

Table 4 shows the performance of formulations 38-41 as a function of the trimethylsilyl triflate concentration. As shown in Table 4, a higher trimethylsilyl triflate concentration generally resulted in a higher percentage of uncollpased features.

TABLE 5

| | | | | Uncol- | |
|---|---|---|---|---|---|
| Form. | Si-Containing | | Rinsing | lapsed | |
| # | Compound | Solvent(s) | liquid | features | Stiffness |
| 42 | 5% trimethyl- | 95% butyl | IPA¹ | 85.1% | 26 mN/m |
| | silyl triflate | acetate | | | |
| 43 | 5% trimethyl- | 95% butyl | IPA/DIW² = | 80.8% | 26 mN/m |
| | silyl triflate | acetate | 90/10 (wt %) | | |
| 44 | 5% trimethyl- | 95% butyl | IPA/DIW = | 86.2% | 26 mN/m |
| | silyl triflate | acetate | 62/38 (wt %) | | |

¹“IPA” refers 2-propanol
²“DIW” refers to deionized water

Table 5 shows the performance of formulations 42-44 by using different rinsing liquids. As shown in Table 5, all three tested rinsing liquid were able to achieve relatively high percentages of uncollpased features.

Other embodiments are within the scope of the following claims.

What is claimed is:

1. A method for treating a semiconductor substrate having a pattern disposed on a surface of a wafer, comprising:
contacting the surface with a surface treatment composition to form a surface treatment layer such that the surface treatment layer has a water contact angle of at least about 50 degrees, the surface treatment composition comprising at least one solvent and at least one trialkylsilyl compound selected from the group consisting of trialklylsilyl alkylsulfonates, trialklylsilyl arylsulfonates, and trialklylsilyl acetates;
wherein the surface treatment composition is substantially free of propylene glycol methyl ether acetate and is substantially free of an additional Si-containing compound other than the at least one trialkylsilyl compound, and the pattern comprises a feature having a dimension of at most about 20 nm.

2. The method of claim 1, wherein the at least one trialkylsilyl compound comprises a SiR₃ group, in which each R, independently, is C₁-C₁₆ alkyl or C₁-C₁₆ haloalkyl.

3. The method of claim 1, wherein the at least one trialkylsilyl compound comprises a trimethylsilyl group, a triethylsilyl group, a tripropylsilyl group, or a tributylsilyl group.

4. The method of claim 1, wherein the at least one trialkylsilyl compound comprises trialkylsilyl methanesulfonate, trialkylsilyl trifluoromethanesulfonate, trialkylsilyl perfluorobutanesulfonate, trialkylsilyl p-toluenesulfonate, trialkylsilyl benzenesulfonate, trialkylsilyl trifluoroacetate, trialkylsilyl trichloroacetate, or trialkylsilyl tribromoacetate.

5. The method of claim 1, wherein the at least one trialkylsilyl compound is from about 0.1 wt % to about 15 wt % of the surface treatment composition.

6. The method of claim 1, wherein the at least one solvent is selected from the group consist of anhydrides, nitriles, glycol ethers, glycol ether acetates, alkanes, aromatic hydrocarbons, sulfones, sulfoxides, ketones, aldehydes, esters, lactams, lactones, acetals, hemiacetals, carboxylic acids, sulfonic acids, and ethers.

7. The method of claim 1, wherein the at least one solvent comprises acetic anhydride, propionic anhydride, trifluoroacetic anhydride, acetonitrile, a C₆-C₁₆ alkane, toluene, xylene, mesitylene, tetraethylene glycol dimethyl ether, propylene glycol dimethyl ether, ethylene glycol dimethyl ether, dipropylene glycol dimethyl ether, diethylene glycol dimethyl ether, diethylene glycol diethyl ether, dipropylene glycol dibutyl ether, n-dibutyl ether, anisole, dimethyl sulfone, dimethyl sulfoxide, sulfolane, propylene carbonate, methyl ethyl ketone, cyclohexanone, n-butyl acetate, hexyl acetate, benzyl acetate, amyl acetate, ethyl propionate, ethyl butanoate, propyl propionate, methyl butanoate, acetic acid, formic acid, methanesulfonic acid, trifluoroacetic acid, isobutyl methyl ketone, N-methyl-pyrrolidone, hydrofluoroethers, or a combination thereof.

8. The method of claim 1, wherein the at least one solvent is from about 1 wt % to about 99 wt % of the surface treatment composition.

9. The method of claim 1, wherein the surface treatment composition is substantially free of water.

10. The method of claim 1, wherein the surface treatment composition consists of the at least one trialkylsilyl compound and the at least one solvent.

11. The method of claim 1, wherein the surface treatment composition has a flash point of at least about 10° C.

12. The method of claim 1, further comprising contacting the surface with at least one aqueous cleaning solution before contacting the surface with the surface treatment composition.

13. The method of claim 12, wherein the at least one aqueous cleaning solution comprise water, an alcohol, aqueous ammonium hydroxide, aqueous hydrochloric acid, aqueous hydrogen peroxide, an organic solvent, or a combination thereof.

14. The method of claim 12, further comprising contacting the surface with a first rinsing solution after contacting the surface with the at least one aqueous cleaning solution but before contacting the surface with the surface treatment composition.

15. The method of claim 1, further comprising contacting the surface with a second rinsing solution after contacting the surface with the surface treatment composition.

16. The method of claim 1, further comprising drying the surface.

17. The method of claim 1, further comprising removing the surface treatment layer.

18. The method of claim 1, wherein the surface comprises SiO₂, SiN, TiN, SiOC, SiON, Si, SiGe, Ge, or W.

19. A surface treatment composition, comprising:
at least one trialkylsilyl compound in an amount of from about 0.1 wt % to about 15 wt % of the surface treatment composition, the at least one trialkylsilyl compound being selected from the group consisting of trialklylsilyl alkylsulfonates, trialklylsilyl arylsulfonates, and trialklylsilyl acetates; and
at least one solvent in an amount of from about 1 wt % to about 99 wt % of the surface treatment composition;
wherein the surface treatment composition is substantially free of propylene glycol methyl ether acetate and is substantially free of an additional Si-containing compound other than the at least one trialkylsilyl compound.

20. The composition of claim 19, wherein the at least one trialkylsilyl compound comprises a SiR₃ group, in which each R, independently, is C₁-C₁₆ alkyl or C₁-C₁₆ haloalkyl.

21. The composition of claim 19, wherein the at least one trialkylsilyl compound comprises a trimethylsilyl group, a triethylsilyl group, a tripropylsilyl group, or a tributylsilyl group.

22. The composition of claim 19, wherein the at least one trialkylsilyl compound comprises trialkylsilyl methanesulfonate, trialkylsilyl trifluoromethanesulfonate, trialkylsilyl perfluorobutanesulfonate, trialkylsilyl p-toluenesulfonate, trialkylsilyl benzenesulfonate, trialkylsilyl trifluoroacetate, trialkylsilyl trichloroacetate, or trialkylsilyl tribromoacetate.

23. The composition of claim 19, wherein the at least one trialkylsilyl compound is from about 1 wt % to about 10 wt % of the surface treatment composition.

24. The composition of claim 19, wherein the at least one solvent is selected from the group consist of anhydrides, nitriles, glycol ethers, glycol ether acetates, alkanes, aromatic hydrocarbons, sulfones, sulfoxides, ketones, aldehydes, esters, lactams, lactones, acetals, hemiacetals, carboxylic acids, sulfonic acids, and ethers.

25. The composition of claim 19, wherein the at least one solvent comprises acetic anhydride, propionic anhydride, trifluoroacetic anhydride, acetonitrile, a C₆-C₁₆ alkane, toluene, xylene, mesitylene, tetraethylene glycol dimethyl ether, propylene glycol dimethyl ether, ethylene glycol dimethyl ether, dipropylene glycol dimethyl ether, diethylene glycol dimethyl ether, diethylene glycol diethyl ether, dipropylene glycol dibutyl ether, n-dibutyl ether, anisole, dimethyl sulfone, dimethyl sulfoxide, sulfolane, propylene carbonate, methyl ethyl ketone, cyclohexanone, n-butyl acetate, hexyl acetate, benzyl acetate, amyl acetate, ethyl propionate, ethyl butanoate, propyl propionate, methyl butanoate, acetic acid, formic acid, methanesulfonic acid, trifluoroacetic acid, isobutyl methyl ketone, N-methyl-pyrrolidone, hydrofluoroethers, or a combination thereof.

26. The composition of claim 19, wherein the at least one solvent is from about 85 wt % to about 99 wt % of the surface treatment composition.

27. The composition of claim 19, wherein the surface treatment composition is substantially free of water.

28. The composition of claim 19, wherein the surface treatment composition consists of the at least one trialkylsilyl compound and the at least one solvent.

29. The composition of claim 19, wherein the composition has a flash point of at least about 10° C.

30. The composition of claim 19, wherein the composition forms a surface treatment layer on a surface such that the surface treatment layer has a water contact angle of at least about 50 degrees.

31. A method for treating a semiconductor substrate having a pattern disposed on a surface of a wafer, comprising:
contacting the surface with a surface treatment composition to form a surface treatment layer such that the surface treatment layer has a water contact angle of at least about 50 degrees, the surface treatment composition consisting of at least one siloxane compound and at least one trialkylsilyl compound selected from the group consisting of trialklylsilyl alkylsulfonates, trialklylsilyl aryl sulfonates, and trialklylsilyl acetates;
wherein the pattern comprises a feature having a dimension of at most about 20 nm.

32. The method of claim 31, wherein the at least one trialkylsilyl compound comprises a SiR₃ group, in which each R, independently, is C₁-C₁₆ alkyl or C₁-C₁₆ haloalkyl.

33. The method of claim 31, wherein the at least one trialkylsilyl compound comprises a trimethylsilyl group, a triethylsilyl group, a tripropylsilyl group, or a tributylsilyl group.

34. The method of claim 31, wherein the at least one trialkylsilyl compound comprises trialkylsilyl methanesulfonate, trialkylsilyl trifluoromethanesulfonate, trialkylsilyl perfluorobutanesulfonate, trialkylsilyl p-toluenesulfonate, trialkylsilyl benzenesulfonate, trialkylsilyl trifluoroacetate, trialkylsilyl trichloroacetate, or trialkylsilyl tribromoacetate.

35. The method of claim 31, wherein the at least one trialkylsilyl compound is from about 0.1 wt % to about 15 wt % of the surface treatment composition.

36. The method of claim 31, wherein the at least one siloxane compound comprises a disiloxane, an oligosiloxane, a cyclosilxoane, or a polysiloxane.

37. The method of claim 31, wherein the at least one siloxane compound comprises hexamethyldisiloxane, 1,3-diphenyl-1,3-dimethyldisiloxane, 1,1,3,3-tetramethyldisiloxane, 1,1,1-triethyl-3,3-dimethyldisiloxane, 1,1,3,3-tetra-n-octyldimethyldisiloxane, bis(nonafluorohexyl)tetramethyldisiloxane, 1,3-bis(trifluoropropyl)tetramethyldisiloxane, 1,3-di-n-butyltetramethyldisiloxane, 1,3-di-n-octyltetramethyldisiloxane, 1,3-diethyltetramethyldisiloxane, 1,3-diphenyltetramethyldisiloxane, hexa-n-butyldisiloxane, hexaethyldisiloxane, hexavinyldisiloxane, 1,1,1,3,3-pentamethyl-3-acetoxydisiloxane, 1-allyl-1,1,3,3-tetramethyldisiloxane, 1,3-bis(3-aminopropyl)tetramethyldisiloxane, 1,3-bis(heptadecafluoro-1,1,2,2-tetrahydrodecyl)tetramethyldisiloxane, 1,3-divinyltetraphenyldisiloxane, 1,3-divinyltetramethyldisiloxane, 1,3-diallyltetrakis(trimethylsiloxy)disiloxane, 1,3-diallyltetramethyldisiloxane, 1,3-diphenyltetrakis(dimethylsiloxy)disiloxane, (3-chloropropyl)pentamethyldisiloxane, 1,3-divinyltetrakis(trimethylsiloxy)disiloxane, 1,1,3,3-tetraisopropyldisiloxane, 1,1,3,3-tetravinyldimethyldisiloxane, 1,1,3,3-tetracyclopentyldichlorodisiloxane, vinylpentamethyldisiloxane, 1,3-bis(3-chloroisobutyl)tetramethyldisiloxane, hexaphenyldisiloxane, 1,3-bis[(bicyclo[2.2.1]hept-2-enyl)ethyl]tetramethyldisiloxane, 1,1,1-triethyl-3,3,3-trimethyldisiloxane, 1,3-bis(3-methacryloxypropyl)tetramethyldisiloxane, 1,3-bis(chloromethyl)tetramethyldisiloxane, 1,1,3,3-tetramethyl-1,3-diethoxydisiloxane, 1,1,3,3-tetraphenyldimethyldisiloxane, methacryloxypentamethyldisiloxane, pentamethyldisiloxane, 1,3-bis(3-chloropropyl)tetramethyldisiloxane, 1,3-bis(4-hydroxybutyl)tetramethyldisiloxane, 1,3-bis(triethoxysilylethyl)tetramethyldisiloxane, 3-aminopropylpentamethyldisiloxane, 1,3-bis(2-aminoethylaminomethyl)tetramethyldisiloxane, 1,3-bis(3-carboxypropyl)tetramethyldisiloxane, 1,3-dichloro-1,3-diphenyl-1,3-dimethyldisiloxane, 1,3-diethynyltetramethyldisiloxane, n-butyl-1,1,3,3-tetramethyldisiloxane, 1,3-dichlorotetraphenyldisiloxane, 1,3-dichlorotetramethyldisiloxane, 1,3-di-t-butyldisiloxane, 1,3-dimethyltetramethoxydisiloxane, 1,3-divinyltetraethoxydisiloxane, 1,1,3,3-tetraethoxy-1,3-dimethyldisiloxane, vinyl-1,1,3,3-tetramethyldisiloxane, platinum-[1,3-bis(cyclohexyl)imidazol-2-ylidene hexachlorodisiloxane, 1,1,3,3-tetraisopropyl-1-chlorodisiloxane, 1,1,1-trimethyl-3,3,3-triphenyldisiloxane, 1,3-bis(trimethylsiloxy)-1,3-dimethyldisiloxane, 3,3-diphenyltetramethyltrisiloxane, 3-phenylheptamethyltrisiloxane, hexamethylcyclotrisiloxane, n-propylheptamethyltrisiloxane, 1,5-diethoxyhexamethyltrisiloxane, 3-ethylheptamethyltrisiloxane, 3-(tetrahydrofurfuryloxypropyl)heptamethyltrisiloxane, 3-(3,3,3-trifluoropropyl)heptamethyltrisiloxane, 1,1,3,5,5-pentaphenyl-1,3,5-trimethyltrisiloxane, octamethyltrisiloxane, 1,1,5,5-tetraphenyl-1,3,3,5-tetramethyltrisiloxane, hexaphenylcyclotrisiloxane, 1,1,1,5,5,5-hexamethyltrisiloxane, octachlorotrisiloxane, 3-phenyl-1,1,3,5,5-pentamethyltrisiloxane, (3,3,3-trifluoropropyl)methylcyclotrisiloxane, 1,3,5-trivinyl-1,1,3,5,5-pentamethyltrisiloxane, 1,3,5-trivinyl-1,3,5-trimethylcyclotrisiloxane, 3-(3-acetoxypropyl)heptamethyltrisiloxane, 3-(m-pentadecylphenoxypropyl)heptamethyltrisiloxane, limonenyltrisiloxane, 3-dodecylheptamethyltrisiloxane, 3-octylheptamethyltrisiloxane, 1,3,5-triphenyltrimethylcyclotrisiloxane, 1,1,1,3,3,5,5-heptamethyltrisiloxane, 1,1,3,3,5,5-hexamethyltrisiloxane, 1,1,1,5,5,5-hexaethyl-3-methyltrisiloxane, 1,5-dichlorohexamethyltrisiloxane, 3-triacontylheptamethyltrisiloxane, 3-(3-hydroxypropyl)heptamethyltrisiloxane, hexamethylcyclomethylphosphonoxytrisiloxane, 3-octadecylheptamethyltrisiloxane, furfuryloxytrisiloxane, tetrakis(dimethylsiloxy)silane, 1,1,3,3,5,5,7,7-octamethyltetrasiloxane, a diphenyl siloxane-dimethylsiloxane copolymer, 1,3-diphenyl-1,3-dimethyldisiloxane, octamethylcyclotetrasiloxane, 1,3-bis(trimethylsiloxy)-1,3-dimethyldisiloxane, a dimethylsiloxane-[65-70%(60% propylene oxide/40% ethylene oxide)] block copolymer, bis(hydroxypropyl)tetramethyldisiloxane, tetra-n-propyltetramethylcyclotetrasiloxane, octaethylcyclotetrasiloxane, decamethyltetrasiloxane, dodecamethylcyclohexasiloxane, dodecamethylpentasiloxane, tetradecamethylhexasiloxane, hexaphenylcyclotrisiloxane, polydimethylsiloxane, polyoctadecylmethylsiloxane, hexacosyl terminated polydimethylsiloxane, decamethylcyclopentasiloxane, poly(3,3,3-trifluoropropylmethylsiloxane), trimethylsiloxy terminated polydimethylsiloxane, 1,1,3,3,5,5,7,7,9,9-decamethylpentasiloxane, or triethylsiloxy terminated polydiethylsiloxane.

38. The method of claim 31, wherein the at least one siloxane compound is from about 85 wt % to about 99.9 wt % of the surface treatment composition.

39. The method of claim 31, wherein the surface treatment composition has a flash point of at least about 10° C.

40. The method of claim 31, further comprising contacting the surface with at least one aqueous cleaning solution before contacting the surface with the surface treatment composition.

41. The method of claim 40, wherein the at least one aqueous cleaning solution comprise water, an alcohol, aqueous ammonium hydroxide, aqueous hydrochloric acid, aqueous hydrogen peroxide, an organic solvent, or a combination thereof.

42. The method of claim 40, further comprising contacting the surface with a first rinsing solution after contacting the surface with the at least one aqueous cleaning solution but before contacting the surface with the surface treatment composition.

43. The method of claim 31, further comprising contacting the surface with a second rinsing solution after contacting the surface with the surface treatment composition.

44. The method of claim 31, further comprising drying the surface.

45. The method of claim 31, further comprising removing the surface treatment layer.

46. The method of claim 31, wherein the surface comprises SiO₂, SiN, TiN, SiOC, SiON, Si, SiGe, Ge, or W.

47. A surface treatment composition, consisting of:
at least one trialkylsilyl compound in an amount of from about 0.1 wt % to about 15 wt % of the surface treatment composition, the at least one trialkylsilyl compound being selected from the group consisting of trialklylsilyl alkylsulfonates, trialklylsilyl arylsulfonates, and trialklylsilyl acetates; and
at least one siloxane compound in an amount of from about 85 wt % to about 99.9 wt % of the surface treatment composition.

48. The composition of claim 47, wherein the at least one trialkylsilyl compound comprises a SiR₃ group, in which each R, independently, is C₁-C₁₆ alkyl or C₁-C₁₆ haloalkyl.

49. The composition of claim 47, wherein the at least one trialkylsilyl compound comprises a trimethylsilyl group, a triethylsilyl group, a tripropylsilyl group, or a tributylsilyl group.

50. The composition of claim 47, wherein the at least one trialkylsilyl compound comprises trialkylsilyl methanesulfonate, trialkylsilyl trifluoromethanesulfonate, trialkylsilyl perfluorobutanesulfonate, trialkylsilyl p-toluenesulfonate, trialkylsilyl benzenesulfonate, trialkylsilyl trifluoroacetate, trialkylsilyl trichloroacetate, or trialkylsilyl tribromoacetate.

51. The composition of claim 47, wherein the at least one trialkylsilyl compound is from about 1 wt % to about 10 wt % of the surface treatment composition.

52. The composition of claim 47, wherein the at least one siloxane compound comprises a disiloxane, an oligosiloxane, a cyclosilxoane, or a polysiloxane.

53. The composition of claim 47, wherein the at least one siloxane compound comprises hexamethyldisiloxane, 1,3-diphenyl-1,3-dimethyldisiloxane, 1,1,3,3-tetramethyldisiloxane, 1,1,1-triethyl-3,3-dimethyldisiloxane, 1,1,3,3-tetra-n-octyldimethyldisiloxane, bis(nonafluorohexyl)tetramethyldisiloxane, 1,3-bis(trifluoropropyl)tetramethyldisiloxane, 1,3-di-n-butyltetramethyldisiloxane, 1,3-di-n-octyltetramethyldisiloxane, 1,3-diethyltetramethyldisiloxane, 1,3-diphenyltetramethyldisiloxane, hexa-n-butyldisiloxane, hexaethyldisiloxane, hexavinyldisiloxane, 1,1,1,3,3-pentamethyl-3-acetoxydisiloxane, 1-allyl-1,1,3,3-tetramethyldisiloxane, 1,3-bis(3-aminopropyl)tetramethyldisiloxane, 1,3-bis(heptadecafluoro-1,1,2,2-tetrahydrodecyl)tetramethyldisiloxane, 1,3-divinyltetraphenyldisiloxane, 1,3-divinyltetramethyldisiloxane, 1,3-diallyltetrakis(trimethylsiloxy)disiloxane, 1,3-diallyltetramethyldisiloxane, 1,3-diphenyltetrakis(dimethylsiloxy)disiloxane, (3-chloropropyl)pentamethyldisiloxane, 1,3-divinyltetrakis(trimethylsiloxy)disiloxane, 1,1,3,3-tetraisopropyldisiloxane, 1,1,3,3-tetravinyldimethyldisiloxane, 1,1,3,3-tetracyclopentyldichlorodisiloxane, vinylpentamethyldisiloxane, 1,3-bis(3-chloroisobutyl)tetramethyldisiloxane, hexaphenyldisiloxane, 1,3-bis[(bicyclo[2.2.1]hept-2-enyl)ethyl]tetramethyldisiloxane, 1,1,1-triethyl-3,3,3-trimethyldisiloxane, 1,3-bis(3-methacryloxypropyl)tetramethyldisiloxane, 1,3-bis(chloromethyl)tetramethyldisiloxane, 1,1,3,3-tetramethyl-1,3-diethoxydisiloxane, 1,1,3,3-tetraphenyldimethyldisiloxane, methacryloxypentamethyldisiloxane, pentamethyldisiloxane, 1,3-bis(3-chloropropyl)tetramethyldisiloxane, 1,3-bis(4-hydroxybutyl)tetramethyldisiloxane, 1,3-bis(triethoxysilylethyl)tetramethyldisiloxane, 3-aminopropylpentamethyldisiloxane, 1,3-bis(2-aminoethylaminomethyl)tetramethyldisiloxane, 1,3-bis(3-carboxypropyl)tetramethyldisiloxane, 1,3-dichloro-1,3-diphenyl-1,3-dimethyldisiloxane, 1,3-diethynyltetramethyldisiloxane, n-butyl-1,1,3,3-tetramethyldisiloxane, 1,3-dichlorotetraphenyldisiloxane, 1,3-dichlorotetramethyldisiloxane, 1,3-di-t-butyldisiloxane, 1,3-dimethyltetramethoxydisiloxane, 1,3-divinyltetraethoxydisiloxane, 1,1,3,3-tetraethoxy-1,3-dimethyldisiloxane, vinyl-1,1,3,3-tetramethyldisiloxane, platinum-[1,3-bis(cyclohexyl)imidazol-2-ylidene hexachlorodisiloxane, 1,1,3,3-tetraisopropyl-1-chlorodisiloxane, 1,1,1-trimethyl-3,3,3-triphenyldisiloxane, 1,3-bis(trimethylsiloxy)-1,3-dimethyldisiloxane, 3,3-diphenyltetramethyltrisiloxane, 3-phenylheptamethyltrisiloxane, hexamethylcyclotrisiloxane, n-propylheptamethyltrisiloxane, 1,5-diethoxyhexamethyltrisiloxane, 3-ethylheptamethyltrisiloxane, 3-(tetrahydrofurfuryloxypropyl)heptamethyltrisiloxane, 3-(3,3,3-trifluoropropyl)heptamethyltrisiloxane, 1,1,3,5,5-pentaphenyl-1,3,5-trimethyltrisiloxane, octamethyltrisiloxane, 1,1,5,5-tetraphenyl-1,3,3,5-tetramethyltrisiloxane, hexaphenylcyclotrisiloxane, 1,1,1,5,5,5-hexamethyltrisiloxane, octachlorotrisiloxane, 3-phenyl-1,1,3,5,5-pentamethyltrisiloxane, (3,3,3-trifluoropropyl)methylcyclotrisiloxane, 1,3,5-trivinyl-1,1,3,5,5-pentamethyltrisiloxane, 1,3,5-trivinyl-1,3,5-trimethylcyclotrisiloxane, 3-(3-acetoxypropyl)heptamethyltrisiloxane, 3-(m-pentadecylphenoxypropyl)heptamethyltrisiloxane, limonenyltrisiloxane, 3-dodecylheptamethyltrisiloxane, 3-octylheptamethyltrisiloxane, 1,3,5-triphenyltrimethylcyclotrisiloxane, 1,1,1,3,3,5,5-heptamethyltrisiloxane, 1,1,3,3,5,5-hexamethyltrisiloxane, 1,1,1,5,5,5-hexaethyl-3-methyltrisiloxane, 1,5-dichlorohexamethyltrisiloxane, 3-triacontylheptamethyltrisiloxane, 3-(3-hydroxypropyl)heptamethyltrisiloxane, hexamethylcyclomethylphosphonoxytrisiloxane, 3-octadecylheptamethyltrisiloxane, furfuryloxytrisiloxane, tetrakis(dimethylsiloxy)silane, 1,1,3,3,5,5,7,7-octamethyltetrasiloxane, a diphenyl siloxane-dimethylsiloxane copolymer, 1,3-diphenyl-1,3-dimethyldisiloxane, octamethylcyclotetrasiloxane, 1,3-bis(trimethylsiloxy)-1,3-dimethyldisiloxane, a dimethylsiloxane-[65-70%(60% propylene oxide/40% ethylene oxide)] block copolymer, bis(hydroxypropyl)tetramethyldisiloxane, tetra-n-propyltetramethylcyclotetrasiloxane, octaethylcyclotetrasiloxane, decamethyltetrasiloxane, dodecamethylcyclohexasiloxane, dodecamethylpentasiloxane, tetradecamethylhexasiloxane, hexaphenylcyclotrisiloxane, polydimethylsiloxane, polyoctadecylmethylsiloxane, hexacosyl terminated polydimethylsiloxane, decamethylcyclopentasiloxane, poly(3,3,3-trifluoropropylmethylsiloxane), trimethylsiloxy terminated polydimethylsiloxane, 1,1,3,3,5,5,7,7,9,9-decamethylpentasiloxane, or triethylsiloxy terminated polydiethylsiloxane.

54. The composition of claim 47, wherein the at least one siloxane compound is from about 90 wt % to about 99 wt % of the surface treatment composition.

55. An article, comprising:
a semiconductor substrate; and
the surface treatment composition of claim 19 supported by the semiconductor substrate.

56. The article of claim 55, wherein the semiconductor substrate is a silicon wafer, a copper wafer, a silicon dioxide wafer, a silicon nitride wafer, a silicon oxynitride wafer, a carbon doped silicon oxide wafer, a SiGe wafer, or a GaAs wafer.
